(19) United States
(12) Patent Application Publication
(10) Pub. No.: US 2006/0076585 A1
(43) Pub. Date: Apr. 13, 2006

(54) Semiconductor resistor and method for manufacturing the same

(75) Inventors: Yoshiaki Kato, Uozu-shi (JP); Yoshiharu Anda, Uozu-shi (JP); Akiyoshi Tamura, Suita-shi (JP)

Correspondence Address: GREENBLUM & BERNSTEIN, P.L.C., 1950 ROLAND CLARKE PLACE, RESTON, VA, 20191, US

(73) Assignee: Matsushita Electric Industrial, Co., Ltd., Osaka (JP)

(21) Appl. No.: 11/234,172

(22) Filed: Sep. 26, 2005

(30) Foreign Application Priority Data
Sep. 27, 2004 (JP) 2004-280227

(51) Int. Cl. H01L 31/112

(52) U.S. Cl. 257/280

(57) ABSTRACT

An object of the present invention is to provide a semiconductor resistor that allows improvement in saturation voltage characteristics and a method for manufacturing the same. The semiconductor resistor of the present invention is formed on the substrate on which a GaAs FET is formed. The GaAs FET includes: a channel layer; a Schottky layer formed on the channel layer and made of undoped InGaP; and a contact layer formed on the Schottky layer. The semiconductor resistor includes: a contact layer including a part of the contact layer isolated from the GaAs FET; an active region including a part of the Schottky layer and a part of the channel layer, both of which are isolated from the GaAs FET; and two ohmic electrodes formed on the contact layer, and the Schottky layer isolated from the GaAs FET is exposed in an area between the two ohmic electrodes.

### BACKGROUND OF THE INVENTION

(1) Field of the Invention

The present invention relates to a semiconductor resistor that uses a compound semiconductor and a method for manufacturing the same.

(2) Description of the Related Art

Because of their high performance, field-effect transistors having semi-insulating substrates made of GaAs (hereinafter referred to as GaAs FETs) are used for power amplifiers, switches and the like for communication equipment, and in particular for cellular phones. Particularly, monolithic microwave integrated circuits (hereinafter referred to as GaAs MMICs), in which active devices such as these GaAs FETs and passive devices such as semiconductor resistors, metal resistors and capacitors are integrated, are in practical use in various areas.

With the recent rapid developments of cellular phones, the GaAs MMICs have been required to have higher performance. Accordingly, not only active devices but also passive devices that constitute an integrated circuit are required to have higher performance. Semiconductor resistors are also required to have improved distortion characteristics (saturation voltage characteristics) and the like, as is the GaAs FETs, particularly because they are formed utilizing the semiconductor layers that are the conductive layers of GaAs FETs.

FIG. 1A is a top view of a GaAs FET as an active device and a semiconductor resistor as a passive device in a conventional GaAs MMIC, FIG. 1B is a sectional view (a section A-A′ in FIG. 1A) of the GaAs FET and the semiconductor resistor, and FIG. 1C is another sectional view (a section B-B′ in FIG. 1A) of the semiconductor resistor.

A GaAs FET 700 and a semiconductor resistor 710 are formed on the same substrate, and are electrically isolated by a device isolation region 730.

The GaAs FET 700 is composed of a substrate 701 made of semi-insulating GaAS and an epitaxial layer 709 formed by crystal growth of a semiconductor layer on the substrate 701. The epitaxial layer 709 includes the following sequentially stacked layers: a buffer layer 702 made of undoped GaAs for alleviating lattice-mismatching between the epitaxial layer 709 and the substrate 701; a buffer layer 703 made of undoped AlGaAs; a channel layer 704 made of 20-nm-thick undoped In_{0.2}Ga_{0.8}As through which carriers run; a Schottky layer 705, as an electron supplying layer, made of 30-nm-thick AlGaAs on which ions of n-type impurity Si are doped; and a contact layer 706 made of 100-nm-thick n⁺-type GaAs.

Here, two ohmic electrodes 720 are formed on the contact layer 706. A part of the contact layer 706 is removed in an area between these two ohmic electrodes 720, and a gate electrode 721 is formed on the Schottky layer 705 which is exposed on the surface of the epitaxial layer 709. The device isolation region 730 is a groove formed in the channel layer 704 and the Schottky layer 705 so as to separate the GaAs FET 700 and the semiconductor resistor 710.

The semiconductor resistor 710 is composed of the semi-insulating substrate 701; a buffer layer 702 and a buffer layer 703 which are formed sequentially on the substrate 701; an active region 719 formed on the buffer layer 703; and a contact layer 713 formed on the active region 719 and made of 100-nm-thick n⁺-type GaAs. The active region 719 includes a part of the channel layer 704 and a part of the Schottky layer 705, both of which are isolated from the FET 700 by the device isolation region 730, that is, an InGaAs layer 711 and an n-type AlGaAs layer 712.

Here, two ohmic electrodes 722 are formed on the contact layer 713. A part of the contact layer 713 is removed selectively by etching an area between the two ohmic electrodes 722 using the n-type AlGaAs layer 712 underneath the contact layer 713 as a stopper layer. Furthermore, a thin insulating protective film made of SiN or SiO (not shown in the diagrams) is formed on the GaAs MMIC so as to cover the GaAs FET 700 and the semiconductor resistor 710.

Next, a description is given, with reference to the diagrams, of a method for manufacturing the semiconductor resistor 710 having the above-mentioned structure.

FIGS. 2A to 2E are sectional views (sections B-B′ in FIG. 1A) of the semiconductor resistor 710.

First, as shown in FIG. 2A, the epitaxial layer 709 is formed on the substrate 701 by sequentially performing epitaxial growth of the buffer layer 702, the buffer layer 703, the channel layer 704, the Schottky layer 705 and the contact layer 706, using MOCVD (Metal Organic Chemical Vapor Deposition) method, MBE (Molecular Beam Epitaxy) method or the like.

Next, as shown in FIG. 2B, the device isolating region 730 is formed by wet etching of the epitaxial layer 709 using a mixed solution of phosphoric acid, hydrogen peroxide and water, for example, after protecting a predetermined area of the epitaxial layer 709 using a photoresist mask 801. The contact layer 713 and the active region 719 of the semiconductor resister 710 are formed in this manner.

Next, as shown in FIG. 2C, the ohmic electrode 722 is formed by vapor deposition/lift-off method using a photoresist mask and an ohmic metal made of Ni/Au/Ge alloy, for example.

Next, as shown in FIG. 2D, a predetermined area of the contact layer 713 between the two ohmic electrodes 722 is selectively removed by wet etching using a mixed solution of citric acid, hydrogen peroxide and water, for example, after protecting other areas using a photoresist mask 802. The n-type AlGaAs layer 712 of the active region 719 serves as an etching stopper. It should be noted that the resistance of the semiconductor resistor is set to be a desired value by adjusting the size and shape of the area of the contact layer 713 to be etched.

Next, as shown in FIG. 2E, after removing the photoresist pattern 802, a thin insulating protective film 800 made of SiO, SiN or the like is formed on the semiconductor resistor 710 so as to cover the ohmic electrodes 722 and the exposed area of the n-type AlGaAs layer 712. The semiconductor resistor 710 is formed in this manner.

### SUMMARY OF THE INVENTION

The above-mentioned conventional semiconductor resistor has the following problem.

In the conventional semiconductor resistor, the n-type AlGaAs layer 712 underneath the contact layer 713 is used as a resistive layer which is exposed on the surface by selectively etching a predetermined area of the contact layer 713 between the two ohmic electrodes 722. However, since the n-type AlGaAs layer 712 is made of AlGaAs, the n-type AlGaAs layer 712 has a high surface state density. Therefore, the saturation voltage characteristics of the semiconductor resistor are restricted due to the influence of a surface depletion layer, which makes it difficult to improve the performance of the semiconductor resistor.

The present invention has been conceived in order to solve the above problem, and it is therefore an object of the present invention to provide a semiconductor resistor that allows improvement in saturation voltage characteristics, that is, further improvement in its performance.

In order to achieve the above object, the semiconductor resistor of the present invention is formed on a substrate on which an active device is formed, wherein the active device includes: a channel layer; and a Schottky layer formed on the channel layer and made of undoped InGaP, and the semiconductor resistor includes: an active region including a part of the Schottky layer and a part of the channel layer, both of which are isolated from the active device by a device isolation region; a contact layer formed on the active region; and two ohmic electrodes formed on the contact layer, and the Schottky layer is exposed in an area between the two ohmic electrodes. Here, the surface of the active region may be in a same plane as the surface of the device isolation region, the device isolation region may be formed by implanting boron ions, and the substrate may be a compound semiconductor substrate made of GaAs or InP.

In the above-described semiconductor resistor according to the present invention, since the InGaP layer of low surface state density is used as a resistive layer exposed on the surface, it becomes possible to realize a semiconductor resistor that allows improvement in saturation voltage characteristics. Therefore, it becomes possible to realize a semiconductor resistor having better saturation voltage characteristics than a semiconductor resistor that uses an AlGaAs layer or a GaAs layer of high surface state density as a resistive layer exposed on the surface.

The present invention can also be embodied as a method for manufacturing a semiconductor resistor, wherein the semiconductor resistor is formed on a substrate on which an active device is formed, the active device includes: a channel layer; a Schottky layer formed on the channel layer and made of undoped AlGaAs or undoped GaAs; and a contact layer formed on the Schottky layer, and the method includes: isolating a part of the contact layer from the active device by forming a photoresist pattern on the contact layer and removing a predetermined area of the contact layer using the photoresist pattern; forming an active region including a part of the Schottky layer and a part of the channel layer, both of which are isolated from the active device by a device isolation region formed in the Schottky layer and the channel layer by implanting ions using a photoresist pattern; forming two ohmic electrodes on the contact layer isolated from the active device; removing a predetermined area of the contact layer isolated from the active device so that the Schottky layer isolated from the active device is exposed between the two ohmic electrodes; and sulfurating an exposed area of the Schottky layer between the two ohmic electrodes. Alternatively, the present invention can be embodied as a method for manufacturing a semiconductor resistor, wherein the semiconductor resistor is formed on a substrate on which an active device is formed, the active device includes: a channel layer; a Schottky layer formed on the channel layer and made of undoped AlGaAs or undoped GaAs; and a contact layer formed on the Schottky layer, and the method includes: isolating a part of the contact layer from the active device by forming a photoresist pattern on the contact layer and removing a predetermined area of the contact layer using the photoresist pattern; forming an active region including a part of the Schottky layer and a part of the channel layer, both of which are isolated from the active device by a device isolation region formed in the Schottky layer and the channel layer by etching using a photoresist pattern; forming two ohmic electrodes on the contact layer isolated from the active device; removing a predetermined area of the contact layer isolated from the active device so that the Schottky layer isolated from the active device is exposed between the two ohmic electrodes; and sulfurating an exposed area of the Schottky layer between the two ohmic electrodes. Here, the sulfurating may use an ammonium sulfide solution or a sodium sulfide solution.

In the above-described method, since the resistive layer exposed on the surface is sulfurated, the dangling bonds on the surface of the resistive layer are terminated by sulfur, the influence of the surface state on the resistive layer is alleviated, and thus it becomes possible to realize a semiconductor resistor having still better saturation voltage characteristics. Therefore, it is possible to maintain such good saturation voltage characteristics of the semiconductor resistor even in the case where the AlGaAs layer having a high surface state density is used as a resistive layer exposed on the surface.

According to the semiconductor resistor and the method for manufacturing the same of the present invention, an InGaP layer having a low surface state density is used as a resistive layer exposed on the surface, and thus it becomes possible to realize a semiconductor resistor which allows improvement in saturation voltage characteristics. Therefore, it becomes possible to realize a semiconductor resistor having better saturation voltage characteristics than a conventional semiconductor resistor that uses an AlGaAs layer as a resistive layer exposed on the surface.

Furthermore, since the resistive layer exposed on the surface is sulfurated, the influence of the surface state on the resistive layer is alleviated, and thus it becomes possible to realize a semiconductor resistor having still better saturation voltage characteristics. Therefore, it is possible to maintain such good saturation voltage characteristics of the semiconductor resistor even in the case where the AlGaAs layer is used as a resistive layer exposed on the surface.

Accordingly, the present invention makes it possible to provide a semiconductor resistor which achieves still higher performance and is partly responsible for higher performance of a GaAs MMIC. Therefore, it can be used for a wide range of applications such as cellular phones, and has high practical value.

As further information about technical background to this application, the disclosure of Japanese Patent Application No. 2004-280227 filed on Sep. 27, 2004 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A is a top view of a GaAs FET and a semiconductor resistor in a conventional GaAs MMIC;

FIG. 1B is a sectional view (a section A-A′ in FIG. 1A) of the conventional GaAs FET and semiconductor resistor;

FIG. 1C is another sectional view (a section B-B′ in FIG. 1A) of the conventional semiconductor resistor;

FIG. 2A is a sectional view showing a manufacturing method of the conventional semiconductor resistor;

FIG. 2B is a sectional view showing the manufacturing method of the conventional semiconductor resistor;

FIG. 2C is a sectional view showing the manufacturing method of the conventional semiconductor resistor;

FIG. 2D is a sectional view showing the manufacturing method of the conventional semiconductor resistor;

FIG. 2E is a sectional view showing the manufacturing method of the conventional semiconductor resistor;

FIG. 3A is a top view of a GaAs FET and a semiconductor resistor in a GaAs MMIC in a first embodiment of the present invention;

FIG. 3B is a sectional view (a section A-A′ in FIG. 3A) of the GaAs FET and the semiconductor resistor in the first embodiment;

FIG. 3C is a sectional view (a section B-B′ in FIG. 3A) of the semiconductor resistor in the first embodiment;

FIG. 4A is a sectional view showing a manufacturing method of the semiconductor resistor in the first embodiment;

FIG. 4B is a sectional view showing the manufacturing method of the semiconductor resistor in the first embodiment;

FIG. 4C is a sectional view showing the manufacturing method of the semiconductor resistor in the first embodiment;

FIG. 4D is a sectional view showing the manufacturing method of the semiconductor resistor in the first embodiment;

FIG. 4E is a sectional view showing the manufacturing method of the semiconductor resistor in the first embodiment;

FIG. 5 is a diagram showing a comparison result between the saturation voltage characteristics of the semiconductor resistor of the first embodiment and the saturation voltage characteristics of the conventional semiconductor resistor;

FIG. 6A is a top view of a GaAs FET and a semiconductor resistor in a GaAs MMIC in a second embodiment of the present invention;

FIG. 6B is a sectional view (a section A-A′ in FIG. 6A) of the GaAs FET and the semiconductor resistor in the second embodiment;

FIG. 6C is a sectional view (a section B-B′ in FIG. 6A) of the semiconductor resistor in the second embodiment;

FIG. 7A is a sectional view showing a manufacturing method of the semiconductor resistor in the second embodiment;

FIG. 7B is a sectional view showing the manufacturing method of the semiconductor resistor in the second embodiment;

FIG. 7C is a sectional view showing the manufacturing method of the semiconductor resistor in the second embodiment;

FIG. 7D is a sectional view showing the manufacturing method of the semiconductor resistor in the second embodiment;

FIG. 7E is a sectional view showing the manufacturing method of the semiconductor resistor in the second embodiment;

FIG. 7F is a sectional view showing the manufacturing method of the semiconductor resistor in the second embodiment; and

FIG. 8 is a diagram showing a comparison result between the saturation voltage characteristics of the semiconductor resistor of the second embodiment and the saturation voltage characteristics of the conventional semiconductor resistor.

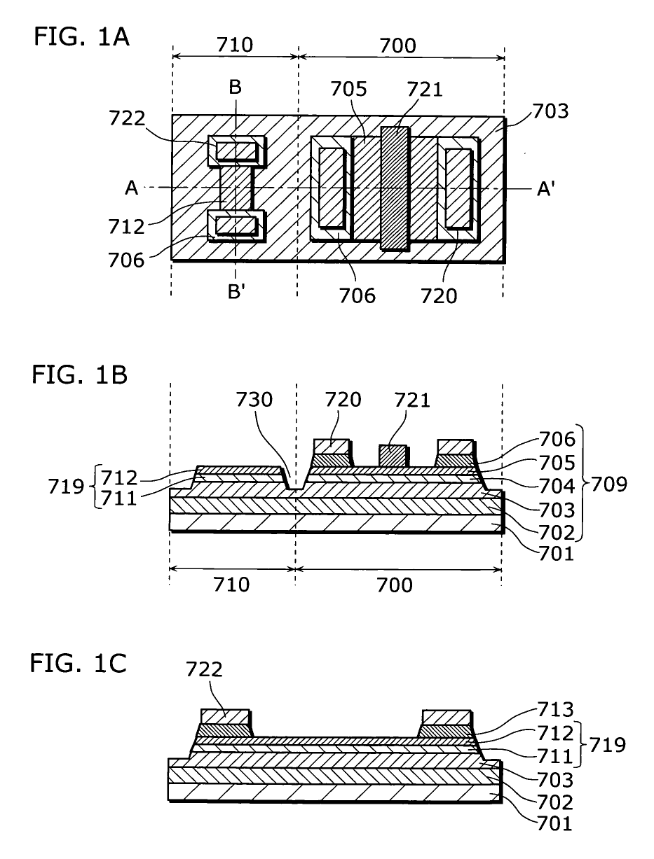

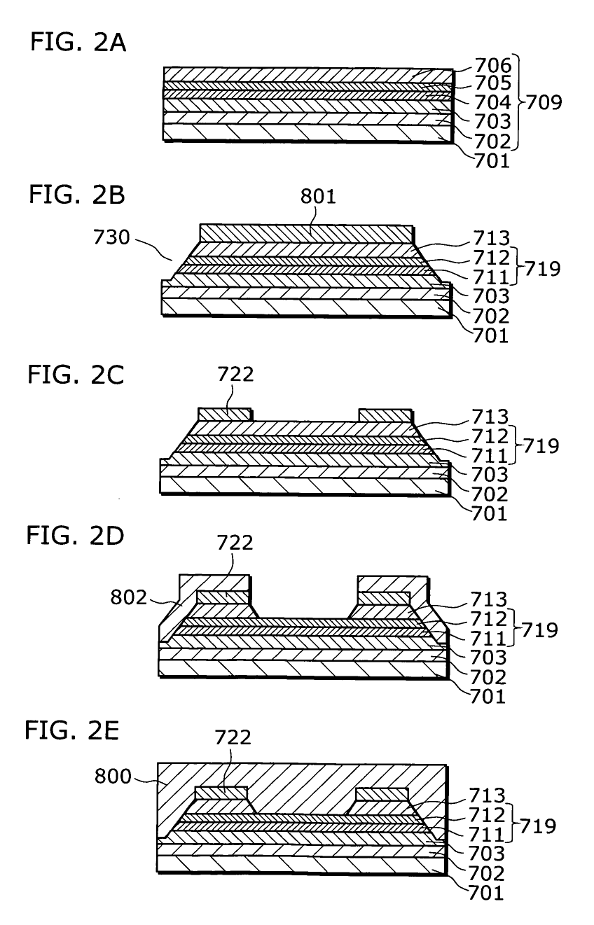

### DESCRIPTION OF THE PREFERRED EMBODIMENT(S)

A semiconductor resistor in the embodiments of the present invention is described below with reference to the diagrams.

### First Embodiment

A GaAs MMIC in a first embodiment of the present invention is described below with reference to the diagrams.

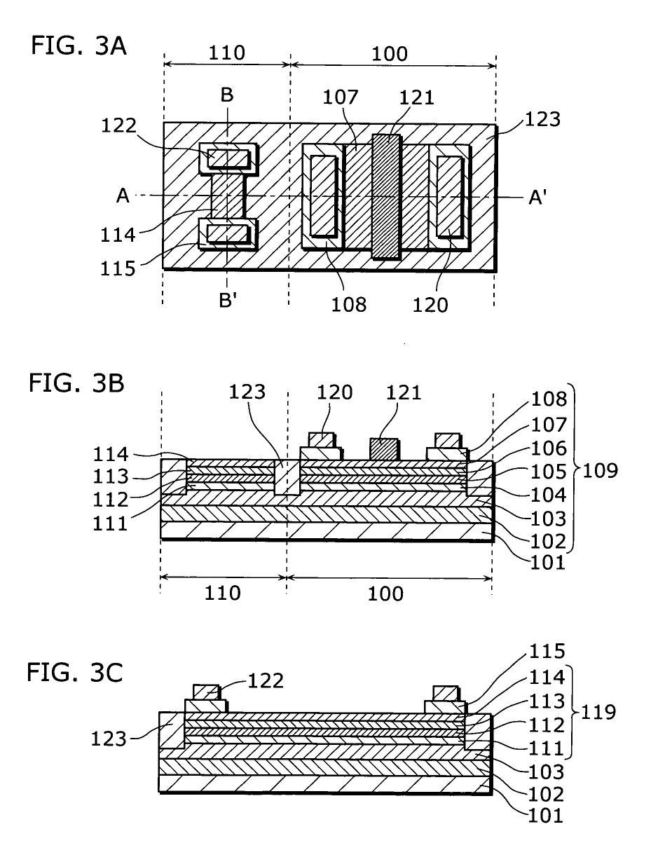

FIG. 3A is a top view of a GaAs FET as an active device and a semiconductor resistor as a passive device in the GaAs MMIC of the first embodiment, FIG. 3B is a sectional view (a section A-A′ in FIG. 3A) of the GaAs FET and the semiconductor resistor, and FIG. 3C is another sectional view (a section B-B′ in FIG. 3A) of the semiconductor resistor.

A GaAs FET 100 and a semiconductor resistor 110 are formed on the same substrate, and are electrically isolated by a device isolation region 123.

The GaAs FET 100 is composed of a substrate 101 made of semi-insulating GaAs and an epitaxial layer 109 formed by crystal growth of a semiconductor layer on the substrate 101. The epitaxial layer 109 includes the following sequentially stacked layers: a buffer layer 102 made of 1-μm-thick undoped GaAs for alleviating lattice-mismatching between the epitaxial layer 109 and the substrate 101; a buffer layer 103 made of undoped AlGaAs; a channel layer 104 made of 20-nm-thick undoped In_{0.2}Ga_{0.8}As through which carriers run; a spacer layer 105 made of 5-nm-thick undoped AlGaAs; a carrier supplying layer 106 made of 10-nm-thick AlGaAs on which an n-type impurity ions Si are doped; a Schottky layer 107 made of 10-nm-thick undoped InGaP; and a contact layer 108 made of 100-nm-thick n⁺-type GaAs.

Here, two ohmic electrodes 120 are formed on the contact layer 108. A part of the contact layer 108 is removed in an area between these two ohmic electrodes 120, and a gate electrode 121 is formed on the Schottky layer 107 which is exposed on the surface of the epitaxial layer 109. The device isolation region 123 is an impurity region formed in the channel layer 104, the spacer layer 105, the carrier supplying layer 106 and the Schottky layer 107 so as to separate the GaAs FET 100 and the semiconductor resistor 110.

The semiconductor resistor 110 is composed of the semi-insulating substrate 101; the buffer layer 102 and the buffer layer 103 which are sequentially formed on the substrate 101; an active region 119 formed on the buffer layer 103; and a contact layer 115 formed on the active region 119 and made of 100-nm-thick n⁺-type GaAs. The active region 119 includes a part of the channel layer 104, a part of the spacer layer 105, a part of the carrier supplying layer 106 and a part of the Schottky layer 107, which are isolated from the FET 100 by the device isolation region 123, that is, an InGaAs layer 111, an AlGaAs layer 112, an n-type AlGaAs layer 113 and an InGaP layer 114.

Here, two ohmic electrodes 122 are formed on the contact layer 115. A part of the contact layer 115 is removed selectively by etching an area between the two ohmic electrodes 122 using the InGaP layer 114 underneath the contact layer 115 as a stopper layer, so that the InGaP layer 114 is exposed on the surface of the active region 119. Furthermore, a thin insulating protective film made of SiN or SiO (not shown in the diagrams) is formed on the GaAs MMIC so as to cover the GaAs FET 100 and the semiconductor resistor 110. The surface of the device isolation region 123 is in the same plane as the surface of the InGaP layer 114 that is the surface of the active region 119.

Next, a description is given, with reference to the diagrams, of a method for manufacturing the semiconductor resistor 110 having the above-mentioned structure.

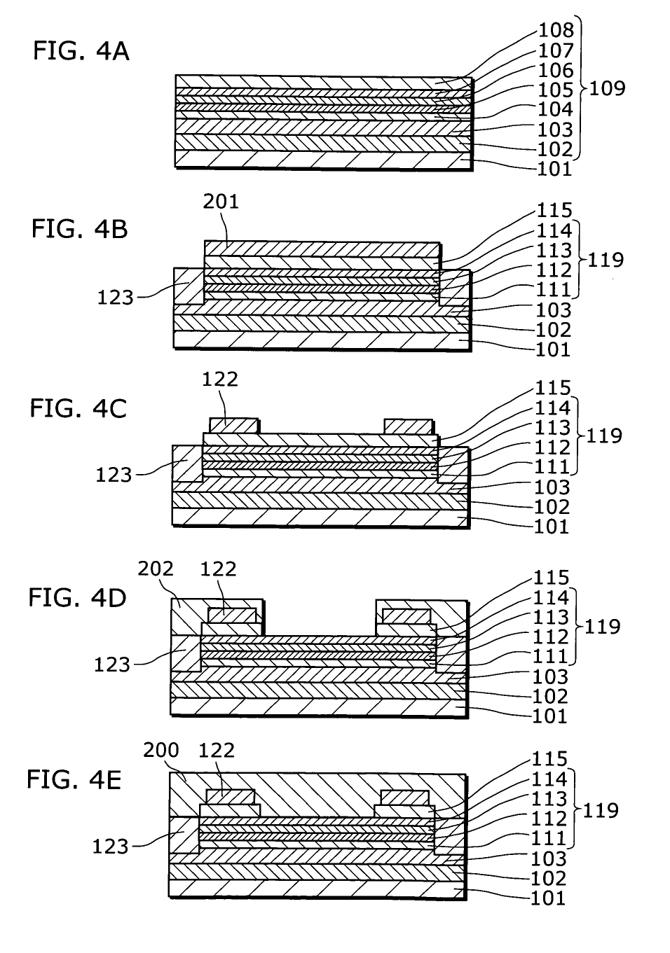

FIGS. 4A to 4E are sectional views of the semiconductor resistor 110.

First, as shown in FIG. 4A, the epitaxial layer 109 is formed on the substrate 101 by performing epitaxial growth of the buffer layer 102, the buffer layer 103, the channel layer 104, the spacer layer 105, the carrier supplying layer 106, the Schottky layer 107 and the contact layer 108 sequentially, using MOCVD method, MBE method or the like.

Next, as shown in FIG. 4B, a part of the contact layer 108 is isolated from the GaAs FET 100 by selectively removing a predetermined area of the contact layer 108 by wet etching using a mixed solution of phosphoric acid, hydrogen peroxide and water, for example, after protecting other areas of the contact layer 108 using a photoresist mask 201. The Schottky layer 107 underneath the contact layer 108 serves as an etching stopper. After that, the device isolation region 123 is formed so that the bottom thereof reaches the buffer layer 103, that is, the region below the channel layer 104, by implanting boron ions, for example, into the Schottky layer 107 exposed on the surface of the epitaxial layer 109 using the photoresist mask 201. The contact layer 115 and the active region 119 of the semiconductor resister 110 are formed in this manner.

Next, as shown in FIG. 4C, after removing the photoresist mask 201, a photoresist pattern (not shown in the diagram) used for forming the ohmic electrode 122 is formed. Then, the ohmic electrode 122 is formed by vapor deposition/lift-off method using an ohmic metal made of Ni/Au/Ge alloy, for example.

Next, as shown in FIG. 4D, a predetermined area of the contact layer 115 between the two ohmic electrodes 122 is selectively removed by wet etching using a mixed solution of phosporic acid, hydrogen peroxide and water, for example, after protecting other areas using a photoresist mask 202. The InGaP layer 114 underneath the contact layer 115 serves as an etching stopper. As a result, the InGaP layer 114 is exposed on the surface between the two island-shaped contact layers 115.

Next, as shown in FIG. 4E, after removing the photoresist pattern 202, a thin insulating protective film 200 made of SiO, SiN or the like is formed on the semiconductor resistor 110 so as to cover the contact layer 115, the exposed area of the InGaP layer 114 and the ohmic electrodes 122. The semiconductor resistor 110 is formed in this manner.

Next, the electrical characteristics of the semiconductor resistor 110 are described below with reference to the diagrams.

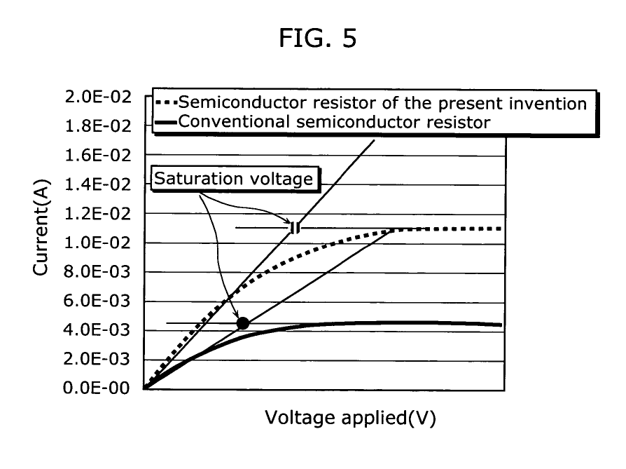

FIG. 5 shows the saturation voltage characteristics of the semiconductor resistor of the present embodiment using an InGaP layer as a resistive layer exposed on the surface, and the saturation voltage characteristics of the conventional semiconductor resistor using an AlGaAs layer as a resistive layer exposed on the surface.

FIG. 5 shows that the semiconductor resistor of the present embodiment using an InGaP layer as a resistive layer exposed on the surface has better saturation voltage characteristics than the conventional semiconductor resistor using an AlGaAs layer as a resistive layer exposed on the surface. This results from the fact that the influence of a surface depletion layer is alleviated by using the InGaP layer of lower surface state density than the AlGaAs layer.

As described above, in the semiconductor resistor of the present embodiment, the InGaP layer 114 is used as a resistive layer exposed on the surface. Therefore, it becomes possible to realize a semiconductor resistor that allows improvement in saturation voltage characteristics.

It should be noted that in the manufacturing method of the semiconductor resistor of the present embodiment, the contact layer 108 is selectively removed by wet etching using the photoresist mask 201, but it may be selectively removed by dry etching using a mixed gas of SiCl₄, SF₆ and N₂, for example.

In the manufacturing method of the semiconductor resistor of the present embodiment, the predetermined area of the contact layer 115 between the two ohmic electrodes 122 is selectively removed by wet etching using the photoresist mask 202, but it may be selectively removed by dry etching using a mixed gas of SiCl₄, SF₆ and N₂, for example.

In the semiconductor resistor of the present embodiment, a combination of the contact layer 115 made of n⁺-type GaAs and a Ni/Au/Ge alloy, as an ohmic metal for the ohmic electrode 122, is used. However, a combination of the contact layer 115 made of n-type InGaAs and a Ti/Pt-base metal that is a nonalloy ohmic contact metal, as an ohmic metal for the ohmic electrode 122, may be used.

Furthermore, in the semiconductor resistor of the present embodiment, the device isolation region 123 is an impurity region formed in the channel layer 104, the spacer layer 105, the carrier supplying layer 106 and the Schottky layer 107 between the GaAs FET 100 and the semiconductor resistor 110. However, the device isolation region 123 may be a groove formed in the channel layer 104, the spacer layer 105, the carrier supplying layer 106 and the Schottky layer 107 so as to penetrate these layers. This groove is formed by wet etching of the Schottky layer 107 exposed on the surface, using the photoresist mask 201 and a mixed solution of phosphoric acid, hydrogen peroxide and water, for example.

Moreover, in the semiconductor resistor of the present embodiment, the substrate 101 is made of GaAs, but the present invention is not limited to such a GaAs substrate, and the substrate 101 may be made of any type of compound semiconductor such as InP.

### Second Embodiment

A GaAs MMIC in a second embodiment of the present invention is described below with reference to the diagrams.

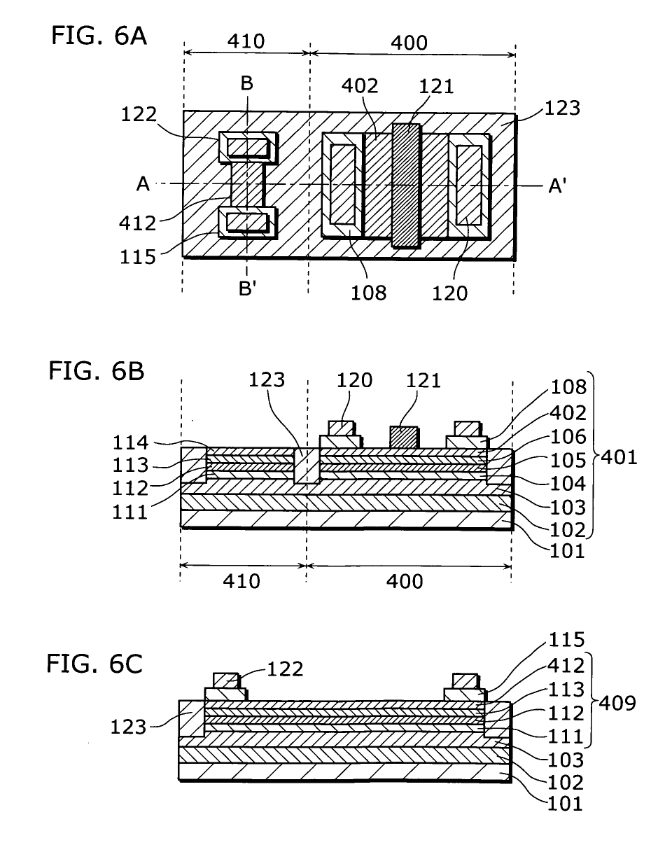

FIG. 6A is a top view of a GaAs FET as an active device and a semiconductor resistor as a passive device in the GaAs MMIC of the second embodiment, FIG. 6B is a sectional view (a section A-A′ in FIG. 6A) of the GaAs FET and the semiconductor resistor, and FIG. 6C is another sectional view (a section B-B′ in FIG. 6A) of the semiconductor resistor. In these diagrams, the same reference numbers are assigned to the elements common to the elements shown in FIGS. 3A to 3C, and the detailed description thereof is not repeated here.

A GaAs FET 400 and a semiconductor resistor 410 are formed on the same substrate, and are electrically isolated by the device isolation region 123.

The GaAs FET 400 is composed of the semi-insulating substrate 101 and an epitaxial layer 401 formed by crystal growth of a semiconductor layer on the substrate 101. The epitaxial layer 401 includes the following sequentially stacked layers: the buffer layer 102 and the buffer layer 103; the channel layer 104; the spacer layer 105; the carrier supplying layer 106; a Schottky layer 402 made of undoped AlGaAs; and the contact layer 108.

Here, two ohmic electrodes 120 are formed on the contact layer 108. A part of the contact layer 108 is removed in an area between these two ohmic electrodes 120, and the gate electrode 121 is formed on the Schottky layer 402 which is exposed on the surface of the epitaxial layer 401. The device isolation region 123 is an impurity region formed in the channel layer 104, the spacer layer 105, the carrier supplying layer 106 and the Schottky layer 402 so as to separate the GaAs FET 400 and the semiconductor resistor 410.

The semiconductor resistor 410 is composed of the semi-insulating substrate 101; the buffer layers 102 and 103 which are sequentially formed on the substrate 101; an active region 409 formed on the buffer layer 103; and the contact layer 115 formed on the active region 409 and made of 100-nm-thick n⁺-type GaAs. The active region 409 includes a part of the channel layer 104, a part of the spacer layer 105, a part of the carrier supplying layer 106 and a part of the Schottky layer 402, which are isolated from the FET 400 by the device isolation region 123, that is, the InGaAs layer 111, the AlGaAs layer 112, the n-type AlGaAs layer 113 and an AlGaAs layer 412 exposed on the surface.

Here, two ohmic electrodes 122 are formed on the contact layer 115. A part of the contact layer 115 is removed selectively by etching an area between the two ohmic electrodes 122 using the AlGaAs layer 412 as a stopper layer, and the AlGaAs layer 412 exposed on the surface of the active region 409 is sulfurated.

Next, a description is given, with reference to the drawings, of a method for manufacturing the semiconductor resistor 410 having the above-mentioned structure. It should be noted that the same reference numbers are assigned to the elements common to the elements shown in FIGS. 4A to 4E, and the detailed description thereof is not repeated here.

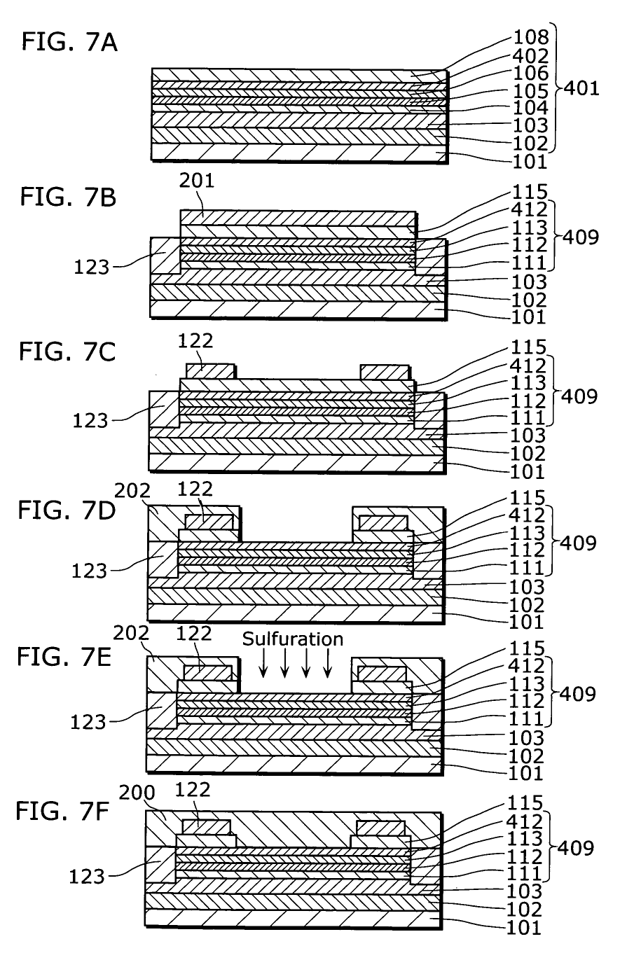

FIGS. 7A to 7F are sectional views of the semiconductor resistor 410.

First, as shown in FIG. 7A, the epitaxial layer 401 is formed on the substrate 101 by performing epitaxial growth of the buffer layer 102, the buffer layer 103, the channel layer 104, the spacer layer 105, the carrier supplying layer 106, the Schottky layer 402 and the contact layer 108 sequentially using MOCVD method, MBE method or the like.

Next, as shown in FIG. 7B, a part of the contact layer 108 is isolated from the GaAs FET 400 by selectively removing a predetermined area of the contact layer 108 by dry etching using a mixed gas of SiCl₄, SF₆ and N₂, for example, after protecting other areas using the photoresist mask 201. The Schottky layer 402 underneath the contact layer 108 serves as an etching stopper. After that, the device isolation region 123 is formed so that the bottom thereof reaches the buffer layer 103, that is, the region below the channel layer 104, by implanting boron ions, for example, into the Schottky layer 402 exposed on the surface of the epitaxial layer 401 further using the photoresist mask 201. The contact layer 115 and the active region 409 of the semiconductor resister 410 are formed in this manner.

Next, as shown in FIG. 7C, after removing the photoresist mask 201, a photoresist pattern (not shown in the diagram) used for forming the ohmic electrode 122 is formed. Then, the ohmic electrode 122 is formed by vapor deposition/lift-off method using an ohmic metal made of Ni/Au/Ge alloy, for example.

Next, as shown in FIG. 7D, a predetermined area of the contact layer 115 between the two ohmic electrodes 122 is selectively removed by wet etching using a mixed solution of citric acid, hydrogen peroxide and water, for example, after protecting other areas using the photoresist mask 202. The AlGaAs layer 412 underneath the contact layer 115 serves as an etching stopper. As a result, the AlGaAs layer 412 is exposed on the surface between the two island-shaped contact layers 115.

Next, as shown in FIG. 7E, the AlGaAs layer 412 exposed on the surface is sulfurated using an ammonium sulfide solution or a sodium sulfide solution, for example, after protecting other areas according to the photoresist pattern 202.

Next, as shown in FIG. 7F, after removing the photoresist pattern 202, the thin insulating protective film 200 made of SiO, SiN or the like is formed on the semiconductor resistor 410 so as to cover the contact layer 115, the exposed area of the AlGaAs layer 412 and the ohmic electrodes 122. The semiconductor resistor 410 is formed in this manner.

Next, the electrical characteristics of the semiconductor resistor 410 are described below with reference to the diagrams.

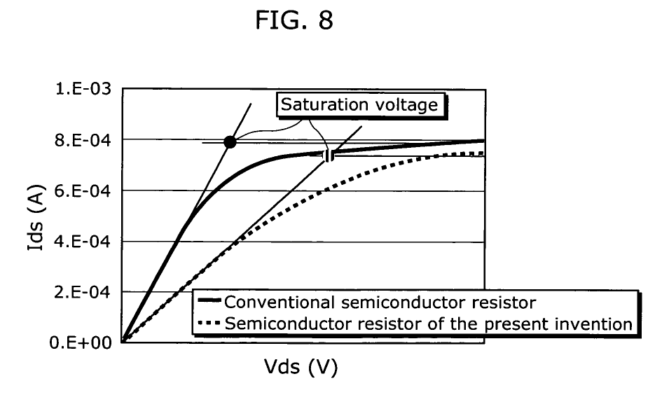

FIG. 8 shows the saturation voltage characteristics of the semiconductor resistor of the present embodiment using a sulfurated AlGaAs layer as a resistive layer, and the saturation voltage characteristics of the conventional semiconductor resistor using an unsulfurated AlGaAs layer as a resistive layer.

FIG. 8 shows that the semiconductor resistor of the present embodiment using a sulfurated AlGaAs layer as a resistive layer has better saturation voltage characteristics than the conventional semiconductor resistor using an unsulfurated AlGaAs layer as a resistive layer. This results from the fact that the dangling bonds on the surface of the AlGaAs layer as a resistive layer are terminated by sulfur and thus the surface state density is reduced.

As described above, according to the manufacturing method of the semiconductor resistor of the present embodiment, the AlGaAs layer 412 is used as a resistive layer exposed on the surface and the exposed portion thereof is sulfurated. Therefore, the dangling bonds on the surface of the resistive layer are terminated by sulfur and the influence of the surface state is reduced, which allows achievement of the semiconductor resistor having still higher saturation voltage characteristics. As a result, even when an AlGaAs layer having a high surface state density is used as a resistive layer, it becomes possible to maintain the favorable saturation voltage characteristics of the semiconductor resistor.

It should be noted that in the manufacturing method of the semiconductor resistor of the present embodiment, the contact layer 108 is selectively removed by dry etching using the photoresist mask 201, but it may be selectively removed by wet etching using the photoresist mask 201 and a mixed solution of phosphoric acid, hydrogen peroxide and water, for example.

In the semiconductore resistor of the present embodiment, a combination of the contact layer 115 made of n⁺-type GaAs and a Ni/Au/Ge alloy, as an ohmic metal for the ohmic electrode 122, is used. However, a combination of the contact layer 115 made of n-type InGaAs and a Ti/Pt-base metal that is a nonalloy ohmic contact metal, as an ohmic metal for the ohmic electrode 122, may be used.

Furthermore, in the semiconductor resistor of the present embodiment, the device isolation region 123 is an impurity region formed in the channel layer 104, the spacer layer 105, the carrier supplying layer 106 and the Schottky layer 402 between the GaAs FET 400 and the semiconductor resistor 410. However, the device isolation region 123 may be a groove formed in the channel layer 104, the spacer layer 105, the carrier supplying layer 106 and the Schottky layer 402 so as to penetrate these layers. This groove is formed by wet etching of the Schottky layer 402 exposed on the surface, using the photoresist mask 201 and a mixed solution of phosphoric acid, hydrogen peroxide and water, for example.

Moreover, in the semiconductor resistor of the present embodiment, AlGaAs is used as a semiconductor material that makes up a resistive layer exposed on the surface, but GaAs may be used. In the case where GaAs is used, the Schottky layer 402 of the GaAs FET 400 is made of GaAs.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention is applicable to a semiconductor resistor and a method for manufacturing the same, and particularly to a GaAs MMIC and the like.

What is claimed is:

1. A semiconductor resistor formed on a substrate on which an active device is formed,
wherein the active device includes: a channel layer; and a Schottky layer formed on said channel layer and made of undoped InGaP,
said semiconductor resistor comprises:
an active region including a part of said Schottky layer and a part of said channel layer, both of which are isolated from the active device by a device isolation region;
a contact layer formed on said active region; and
two ohmic electrodes formed on said contact layer, and
said Schottky layer is exposed in an area between said two ohmic electrodes.

2. The semiconductor resistor according to claim 1,
wherein a surface of said active region is in a same plane as a surface of said device isolation region.

3. The semiconductor resistor according to claim 2,
wherein said device isolation region is formed by implanting boron ions.

4. The semiconductor resistor according to claim 1,
wherein said substrate is a compound semiconductor substrate made of GaAs or InP.

5. A method for manufacturing a semiconductor resistor,
wherein the semiconductor resistor is formed on a substrate on which an active device is formed,
the active device includes: a channel layer; a Schottky layer formed on the channel layer and made of undoped AlGaAs or undoped GaAs; and a contact layer formed on the Schottky layer, and
said method comprises:
isolating a part of the contact layer from the active device by forming a photoresist pattern on the contact layer and removing a predetermined area of the contact layer using the photoresist pattern;
forming an active region including a part of the Schottky layer and a part of the channel layer, both of which are isolated from the active device by a device isolation region formed in the Schottky layer and the channel layer by implanting ions using a photoresist pattern;
forming two ohmic electrodes on the contact layer isolated from the active device;
removing a predetermined area of the contact layer isolated from the active device so that the Schottky layer isolated from the active device is exposed between the two ohmic electrodes; and
sulfurating an exposed area of the Schottky layer between the two ohmic electrodes.

6. The method according to claim 5,
wherein said sulfurating uses an ammonium sulfide solution or a sodium sulfide solution.

7. A method for manufacturing a semiconductor resistor,
wherein the semiconductor resistor is formed on a substrate on which an active device is formed,
the active device includes: a channel layer; a Schottky layer formed on the channel layer and made of undoped AlGaAs or undoped GaAs; and a contact layer formed on the Schottky layer, and
said method comprises:
isolating a part of the contact layer from the active device by forming a photoresist pattern on the contact layer and removing a predetermined area of the contact layer using the photoresist pattern;
forming an active region including a part of the Schottky layer and a part of the channel layer, both of which are isolated from the active device by a device isolation region formed in the Schottky layer and the channel layer by etching using a photoresist pattern;
forming two ohmic electrodes on the contact layer isolated from the active device;
removing a predetermined area of the contact layer isolated from the active device so that the Schottky layer isolated from the active device is exposed between the two ohmic electrodes; and
sulfurating an exposed area of the Schottky layer between the two ohmic electrodes.

8. The method according to claim 7,
wherein said sulfurating uses an ammonium sulfide solution or a sodium sulfide solution.
